(19) United States
(12) Patent Application Publication
(10) Pub. No.: US 2025/0300610 A1
(43) Pub. Date: Sep. 25, 2025

(54) Low Noise Amplifier Circuit Capable of Enhancing Operational Linearity and Noise Reduction Performance

(71) Applicant: Wavetek Microelectronics Corporation, HSINCHU COUNTY (TW)

(72) Inventors: Min-Li Chou, HSINCHU COUNTY (TW); Barry Jia-Fu Lin, HSINCHU COUNTY (TW); Hsien-Chin Chiu, HSINCHU COUNTY (TW)

(73) Assignee: Wavetek Microelectronics Corporation, HSINCHU COUNTY (TW)

(21) Appl. No.: 18/974,829

(22) Filed: Dec. 10, 2024

Related U.S. Application Data
(60) Provisional application No. 63/568,449, filed on Mar. 22, 2024.

(51) Int. Cl. H03F 3/193

(52) U.S. Cl. CPC H03F 3/193; H03F 2200/294; H03F 2200/451

(57) ABSTRACT

A low noise amplifier circuit includes a first transistor, a second transistor, and a first inductor. The first transistor comprises a first terminal coupled to a first filtering circuit, a second terminal coupled to a second filtering circuit, and a control terminal configured to receive an input signal. The second transistor comprises a first terminal configured to output an output signal, a second terminal coupled to the first filtering circuit, and a control terminal. The first inductor includes a first terminal coupled to a high voltage terminal and a second terminal coupled to the first terminal of the second transistor. The second filtering circuit is coupled to a ground terminal.

### CROSS REFERENCE TO RELATED APPLICATIONS

This application claims the benefit of U.S. Provisional Application No. 63/568,449, filed on Mar. 22, 2024. The content of the application is incorporated herein by reference.

### BACKGROUND OF THE INVENTION

### 1. Field of the Invention

The present invention illustrates a low noise amplifier circuit, and more particularly, a low noise amplifier circuit capable of enhancing operational linearity and noise reduction performance.

### 2. Description of the Prior Art

A Low Noise Amplifier (LNA) is a type of electronic amplifier that is specifically designed to amplify weak electrical signals while introducing as little additional noise as possible. These amplifiers are commonly used in the initial stages of a receiver to boost the strength of a signal before it is further processed. In many applications, such as wireless communication, radar, and satellite communication, it is crucial to detect very weak signals. LNAs play a vital role in improving the receiver's sensitivity by amplifying these faint signals.

Operational linearity refers to the ability of a circuit to produce an output signal that is directly proportional to the input signal. For an ideal linear amplifier, doubling the input signal should result in a doubling of the output signal without any distortion. However, non-linearity can introduce distortion, harmonics, and intermodulation products, which can corrupt the original signal and make it difficult to demodulate. Although conventional LNA configuration uses the same type of field-effect transistor (FETs) to achieve low noise performance in various radio frequency integrated circuits (RFICs), its overall performance is hindered by the poor linearity of its constituent components.

Therefore, developing an LNA capable of proving high operational linearity in conjunction with enhanced noise reduction performance is an important issue.

### SUMMARY OF THE INVENTION

In an embodiment of the present invention, a low noise amplifier circuit is disclosed. The low noise amplifier circuit comprises a first transistor, a second transistor, and a first inductor. The first transistor comprises a first terminal coupled to a first filtering circuit, a second terminal coupled to a second filtering circuit, and a control terminal configured to receive an input signal. The second transistor comprises a first terminal configured to output an output signal, a second terminal coupled to the first filtering circuit, and a control terminal. The first inductor comprises a first terminal coupled to a high voltage terminal and a second terminal coupled to the first terminal of the second transistor. The second filtering circuit is coupled to a ground terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a structure of a low noise amplifier circuit according to a first embodiment of the present invention.

FIG. 2 is a structure of a low noise amplifier circuit according to a second embodiment of the present invention.

FIG. 3 is a structure of a low noise amplifier circuit according to a third embodiment of the present invention.

FIG. 4 is a structure of a low noise amplifier circuit according to a fourth embodiment of the present invention.

FIG. 5 is a structure of a low noise amplifier circuit according to a fifth embodiment of the present invention.

FIG. 6 is a structure of a low noise amplifier circuit according to a sixth embodiment of the present invention.

FIG. 7 is a structure of a low noise amplifier circuit according to a seventh embodiment of the present invention.

FIG. 8 is a structure of a low noise amplifier circuit according to an eighth embodiment of the present invention.

### DETAILED DESCRIPTION

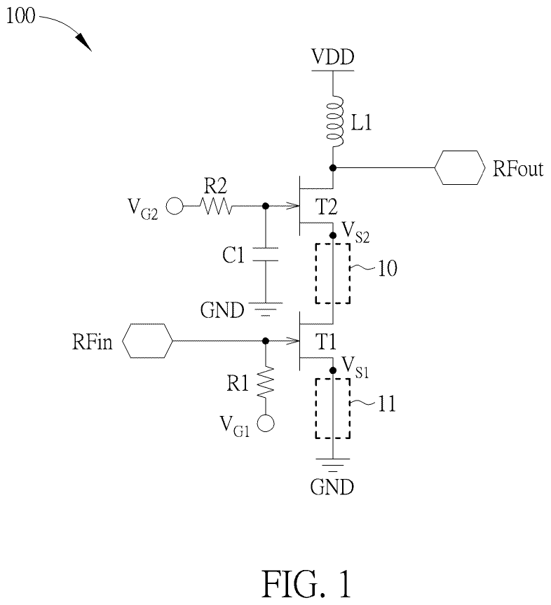

FIG. 1 is a structure of a low noise amplifier circuit 100 according to a first embodiment of the present invention. The low noise amplifier circuit 100 includes a first transistor T1 (bottom transistor in FIG. 1) and a second transistor T2 (top transistor in FIG. 1). The first transistor T1 includes a first terminal coupled to a first filtering circuit 10, a second terminal coupled to a second filtering circuit 11, and a control terminal configured to receive an input signal RFin. The second transistor T2 includes a first terminal configured to output an output signal RFout, a second terminal coupled to the first filtering circuit 10, and a control terminal. The first inductor L1 includes a first terminal coupled to a high voltage terminal VDD, and a second terminal coupled to the first terminal of the second transistor T2. Here, the second filtering circuit 11 is coupled to a ground terminal GND. In the low noise amplifier circuit 100, the first transistor T1 can be an enhancement mode field-effect transistor (E-mode FET). The second transistor T2 can be a depletion mode field-effect transistor (D-mode FET). Specifically, a gate length of the second transistor T2 (D-mode FET) is greater than a gate length of the first transistor T1 (E-mode FET). Therefore, since the gate length of the second transistor T2 is greater than the gate length of the first transistor T1, when the second transistor T2 is a D-mode FET having a wide gate length, the operational linearity of the noise amplifier circuit 100 can be enhanced. Further, the noise reduction performance of the noise amplifier circuit 100 can be maintained by using the E-mode FET (first transistor T1) having a narrow gate length. Further, the first transistor T1 or the second transistor T2 can be formed by a Gallium arsenide (GaAs) semiconductor material or a Gallium nitride (GaN) semiconductor material. However, the present invention is not limited thereto. Any reasonable hardware modification falls into the scope of the present invention.

In FIG. 1, as previously mentioned, the first transistor T1 is used for reducing noise interference from the input signal RFin according to a Friis formula. The second transistor T2 is used for enhancing operational linearity between the input signal RFin and the output signal RFout. Details are illustrated below. The Friis formula can be expressed as:

$$F = {F}_{1} + \frac{{F}_{2} - 1}{{G}_{1}} + \frac{{F}_{3} - 1}{{G}_{1} {G}_{2}} + \frac{{F}_{4} - 1}{{G}_{1} {G}_{2} {G}_{3}} + …$$

Here, F denotes as a total noise factor of the low noise amplifier circuit 100. F₁ denotes a noise factor of a first stage amplifier. F₂ denotes a noise factor of a second stage amplifier, and so on. G₁ denotes a gain factor of the first stage amplifier. G₂ denotes a gain factor of second stage amplifier, and so on. The Friis formula can be used for calculating the total noise factor F of the “multi-stage” low noise amplifier, such as the low noise amplifier circuit 100 (two-stages). In the low noise amplifier circuit 100, the first stage amplifier is performed by the first transistor T1. The second stage amplifier is performed by the second transistor T2. Particularly, in the Friis formula, the total noise factor F is dominated by the noise factor F₁ of a first stage amplifier (or say, F₁ is a dominating term). In other words, the total noise factor F can be mostly reduced by lower noise factor F₁ of the first stage amplifier. Therefore, when the first transistor T1 is the E-mode FET having the narrow gate length, it can provide lower noise factor F₁ of the first stage amplifier, resulting in reduced total noise factor F. Further, since the total noise factor F of the low noise amplifier circuit 100 can be reduced by using the first transistor T1, the second transistor T2 can be used for enhancing operational linearity of the low noise amplifier circuit 100. Configurations of the first transistor T1 and the second transistor T2 are illustrated below.
(a) The first transistor T1 is the E-mode FET having the narrow gate length used in bottom FET. Based on the Friis formula, the first stage is a key stage for low noise performance of the low noise amplifier circuit 100.
(b) The second transistor T2 is the D-mode FET having the wide gate length used in top FET. The final stage using high linearity device can enhance overall linearity performance of the low noise amplifier circuit 100.

In FIG. 1, the low noise amplifier circuit 100 further includes a first resistor R1, a second resistor R2, and a first capacitor C1. The first resistor R1 includes a first terminal coupled to the control terminal of the first transistor T1, and a second terminal configured to receive a first gate bias voltage V_{G1}. The second resistor R2 includes a first terminal coupled to the control terminal of the second transistor T2, and a second terminal configured to receive a second gate bias voltage V_{G2}. The first capacitor C1 includes a first terminal coupled to the first terminal of the second resistor R2, and a second terminal coupled to the ground terminal GND. The first terminal of the first capacitor C1 is couple to the control terminal of the second transistor T2. Particularly, the first capacitor C1 is used for AC (Alternating Current) grounding, allowing the second transistor T2 performing a function of a common-gate configuration device of the cascode circuit. For the second resistor R2, it can block an AC signal and pass through the direct current (DC) supply of the second gate bias voltage V_{G2}. Further, in the low noise amplifier circuit 100, the first gate bias voltage V_{G1} and the second gate bias voltage V_{G2} can be positive voltages. For example, when a voltage of the second terminal (say, “V_{S2}”) of the second transistor T2 is greater than the second gate bias voltage V_{G2} (say, V_{S2}>V_{G2}), it implies that a gate-source voltage VG_{S2}=V_{G2}−V_{S2} of the second transistor T2 is a negative voltage. As a result, a channel can be controlled by the second transistor T2 (D-mode FET) according to the negative gate-source voltage V_{GS2}. Further, since the second terminal of the first transistor T1 is coupled to the ground terminal GND, when the first gate bias voltage V_{G1} is a positive voltage, the first transistor T1 can be turned on according to the positive first gate bias voltage V_{G1}. As a result, since the first gate bias voltage V_{G1} and the second gate bias voltage V_{G2} can be positive voltages, complexity of a power supply of the first gate bias voltage V_{G1} and the second gate bias voltage V_{G2} can be reduced. Therefore, the low noise amplifier circuit 100 can be applied to low-complexity circuit applications.

In FIG. 1, the first filtering circuit 10 includes a first transmission line. Therefore, the first terminal of the first transistor T1 can be coupled to the second terminal of the second transistor T2 through the first transmission line. The second filtering circuit 11 includes a second transmission line. The second terminal of the first transistor T1 is coupled to the ground terminal GND through the second transmission line. Here, the noise amplifier circuit 100 can be a “cascode” noise amplifier circuit including a common-source configuration device (i.e., the first transistor T1) and a common-gate configuration (i.e., the second transistor T2). However, the first filtering circuit 10 and the second filtering circuit 11 can be designed as various circuit structures for different applications, as illustrated below.

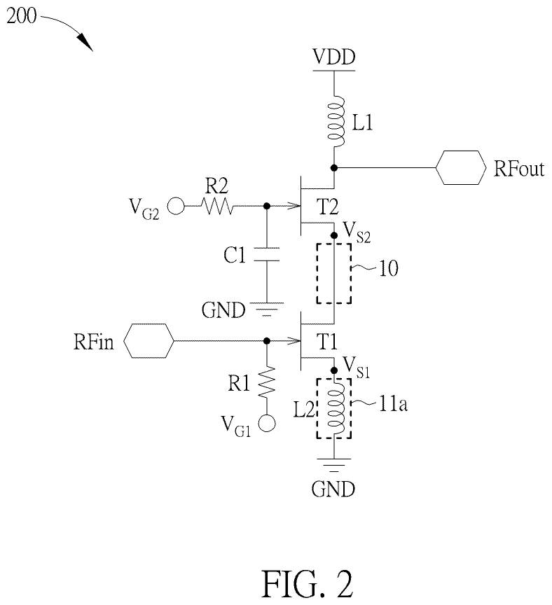

FIG. 2 is a structure of a low noise amplifier circuit 200 according to a second embodiment of the present invention. For avoid ambiguity, a low noise amplifier circuit in FIG. 2 is called as the low noise amplifier circuit 200 hereafter. A circuit structure of the low noise amplifier circuit 200 is similar to the circuit structure of the low noise amplifier circuit 100. A difference between the low noise amplifier circuit 100 and the low noise amplifier circuit 200 is the “second filtering circuit 11”, called as the second filtering circuit 11a hereafter. In FIG. 2, the second filtering circuit 11a includes a second inductor L2. The second inductor L2 includes a first terminal coupled to the second terminal of the first transistor T1, and a second terminal coupled to the ground terminal GND. The first inductor L1 is configured to block an alternating current (AC). The second inductor L2 is configured to adjust an AC impedance of the first transistor T1. Therefore, the AC can still pass through to the ground with low leakage signal. Actually, the first inductor L1 (as shown in the second filtering circuit 11a) or the second transmission line (as shown in the second filtering circuit 11) coupled to the first transistor T1 can improve noise performance. Such structures can be called as a “source denegation” structure.

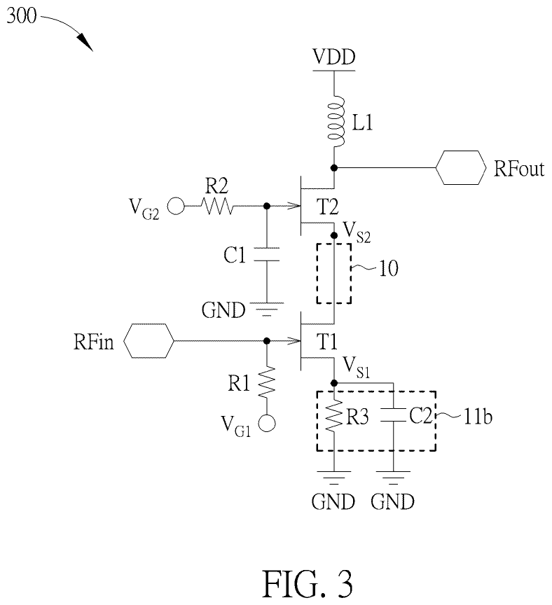

FIG. 3 is a structure of a low noise amplifier circuit 300 according to a third embodiment of the present invention. For avoid ambiguity, a low noise amplifier circuit in FIG. 3 is called as the low noise amplifier circuit 300 hereafter. A circuit structure of the low noise amplifier circuit 200 is similar to the circuit structure of the low noise amplifier circuit 100. A difference between the low noise amplifier circuit 100 and the low noise amplifier circuit 300 is the “second filtering circuit 11”, called as the second filtering circuit 11b hereafter. In FIG. 3, the second filtering circuit 11b includes a third resistor R3 and a second capacitor C2. The third resistor R3 includes a first terminal coupled to the second terminal of the first transistor T1, and a second terminal coupled to the ground terminal GND. The second capacitor C2 includes a first terminal coupled to the first terminal of the third resistor R3, and a second terminal coupled to the ground terminal GND. Here, the third resistor R3 is configured to boost a voltage (V_{S1}) of the second terminal of the first transistor T1 so as to change a gate-source voltage of the first transistor to a negative voltage. For example, the first gate bias voltage V_{G1} can be a positive voltage. When the voltage V_{S1} of the first transistor T1 is boosted by the third resistor R3 higher than the first gate bias voltage V_{G1} (say, V_{S1}>V_{G1}), a gate-source voltage V_{GS1} of the first transistor T1 is the negative voltage (say, V_{GS1}=V_{G1}−V_{S1}<0). By doing so, the first transistor T1 can be the D-mode FET. The first transistor T1 can be turned on according to the negative gate-source voltage V_{GS1}. Negative first gate bias voltage V_{G1} is not required. It should be understood that any loaded component such as FET or resistor can be applied to the second filtering circuit 11b for generating higher positive voltage V_{S1} on a source terminal of the first transistor T1 (D-mode FET).

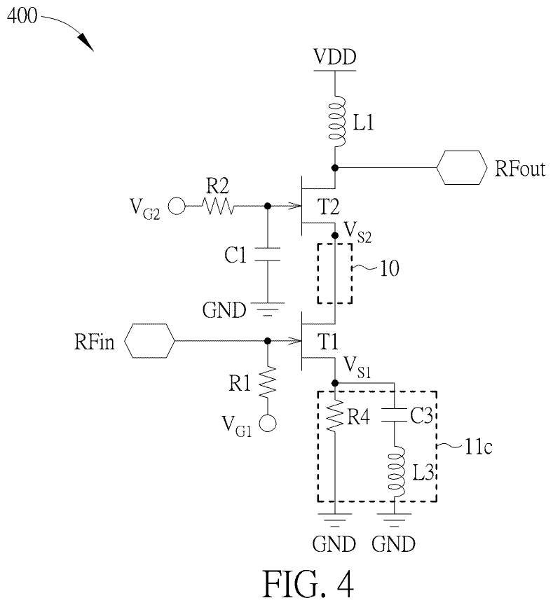

FIG. 4 is a structure of a low noise amplifier circuit 400 according to a fourth embodiment of the present invention. For avoid ambiguity, a low noise amplifier circuit in FIG. 4 is called as the low noise amplifier circuit 400 hereafter. A circuit structure of the low noise amplifier circuit 400 is similar to the circuit structure of the low noise amplifier circuit 100. A difference between the low noise amplifier circuit 100 and the low noise amplifier circuit 400 is the “second filtering circuit 11”, called as the second filtering circuit 11c hereafter. In FIG. 4, the second filtering circuit 11c includes a fourth resistor R4, a third capacitor C3, and a third inductor L3. The fourth resistor R4 includes a first terminal coupled to the second terminal of the first transistor T1, and a second terminal coupled to the ground terminal GND. The third capacitor C3 includes a first terminal couple to the first terminal of the fourth resistor R4, and a second terminal. The third inductor L3 includes a first terminal coupled to the second terminal of the third capacitor C3, and a second terminal coupled to the ground terminal GND. Here, the fourth resistor R4 is configured to boost the voltage (V_{S1}) of the second terminal of the first transistor T1 so as to change the gate-source voltage of the first transistor to a negative voltage. For example, the first gate bias voltage V_{G1} can be a positive voltage. When the voltage V_{S1} of the first transistor T1 is boosted by the fourth resistor R4 higher than the first gate bias voltage V_{G1} (say, V_{S1}>V_{G1}), the gate-source voltage V_{GS1} of the first transistor T1 is the negative voltage (say, V_{GS1}=V_{G1}−V_{S1}<0). By doing so, the first transistor T1 can be the D-mode FET. The channel can be controlled by the first transistor T1 according to the negative gate-source voltage V_{GS1}. Negative first gate bias voltage V_{G1} is not required. Similarly, it should be understood that any loaded component such as FET or resistor can be applied to the second filtering circuit 11c for generating higher positive voltage V_{S1} on the source terminal of the first transistor T1 (D-mode FET). Particularly, as previously mentioned, the first transistor T1 can be regarded as a common-source configuration device. In should be understood that, in the common-source configuration device a resistor or an inductor (i.e., such as the third inductor L3) can be inserted between the source terminal of the transistor (such as the first transistor T1) and the ground terminal GND. This resistor or inductor (i.e., such as the third inductor L3) can be called as a degeneration resistor or a degeneration inductor. When an AC signal passes through the first transistor T1, it creates a voltage drop across the degeneration resistor or the degeneration inductor. This voltage drop is fed back to the gate of the first transistor T1, which in turn reduces the transconductance of the first transistor T1. As a result, it can reduce the non-linear distortion of the first transistor T1, thereby improving the linearity and noise reduction efficiency of the amplifier.

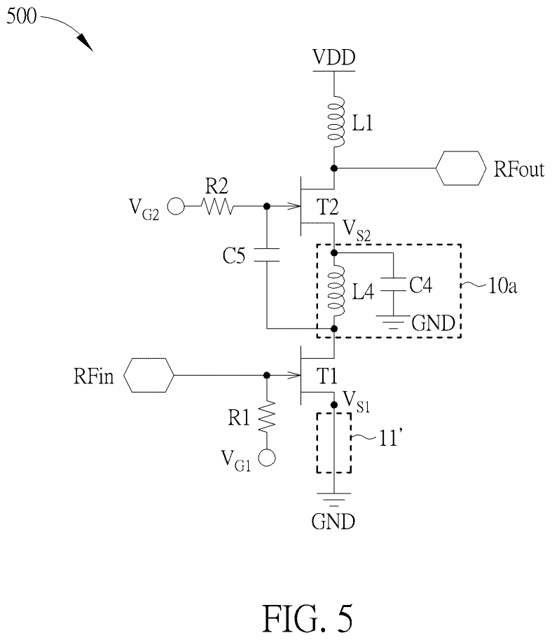

FIG. 5 is a structure of a low noise amplifier circuit 500 according to a fifth embodiment of the present invention. For avoid ambiguity, a low noise amplifier circuit in FIG. 5 is called as the low noise amplifier circuit 500 hereafter. A circuit structure of the low noise amplifier circuit 500 is similar to the circuit structure of the low noise amplifier circuit 100. A difference between the low noise amplifier circuit 100 and the low noise amplifier circuit 500 is the “first filtering circuit 10” coupled to the first transistor T1 and the second transistor T2, called as the first filtering circuit 10a hereafter. The first filtering circuit 10a includes a fourth inductor L4 and a fourth capacitor C4. The fourth inductor L4 includes a first terminal coupled to the second terminal of the second transistor T2, and a second terminal coupled to the first terminal of the first transistor T1. The fourth capacitor C4 includes a first terminal coupled to the first terminal of the fourth inductor L4, and a second terminal coupled to the ground terminal GND. Further, the fifth capacitor C5 is configured to direct the AC signal from the first terminal (drain terminal) of the first transistor T1 to the control terminal (gate terminal) of the second transistor T2. Similarly, the second filtering circuit 11′ includes a second transmission line. The second terminal of the first transistor T1 is coupled to the ground terminal GND through the second transmission line.

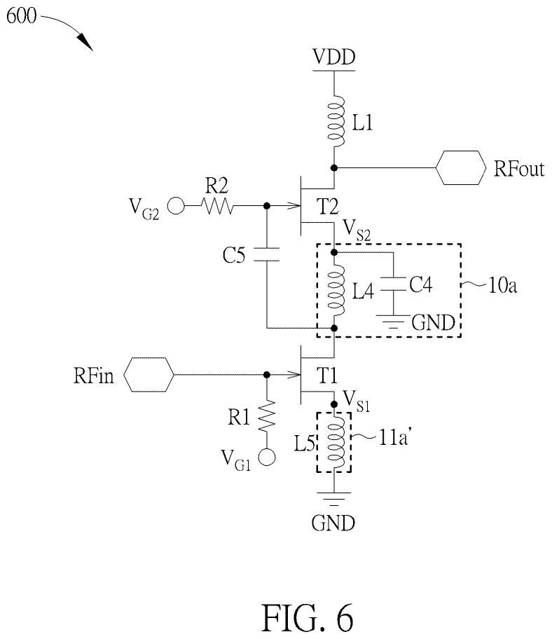

FIG. 6 is a structure of a low noise amplifier circuit 600 according to a sixth embodiment of the present invention. For avoid ambiguity, a low noise amplifier circuit in FIG. 6 is called as the low noise amplifier circuit 600 hereafter. A circuit structure of the low noise amplifier circuit 600 is similar to the circuit structure of the low noise amplifier circuit 500. A difference between the low noise amplifier circuit 500 and the low noise amplifier circuit 600 is the “second filtering circuit 11”, called as the second filtering circuit 11a′ hereafter. In FIG. 2, the second filtering circuit 11a′ includes a fifth inductor L5. The fifth inductor L5 includes a first terminal coupled to the second terminal of the first transistor T1, and a second terminal coupled to the ground terminal GND. The first inductor L1, the fourth inductor L4, and the fifth inductor L5 can be configured to block an alternating current (AC) passing through the low noise amplifier circuit 500. Actually, the first inductor L1 (as shown in the second filtering circuit 11a′) or the second transmission line (as shown in the second filtering circuit 11′) coupled to the first transistor T1 can improve noise performance. Such structures can be called as the “source denegation” structure.

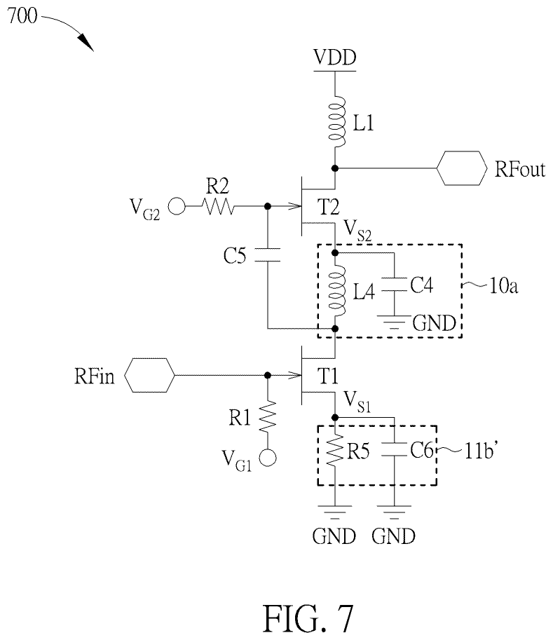

FIG. 7 is a structure of a low noise amplifier circuit 700 according to a seventh embodiment of the present invention. For avoid ambiguity, a low noise amplifier circuit in FIG. 7 is called as the low noise amplifier circuit 700 hereafter. A circuit structure of the low noise amplifier circuit 700 is similar to the circuit structure of the low noise amplifier circuit 500. A difference between the low noise amplifier circuit 500 and the low noise amplifier circuit 700 is the “second filtering circuit 11”, called as the second filtering circuit 11b′ hereafter. In FIG. 7, the second filtering circuit 11b′ includes a fifth resistor R5 and a sixth capacitor C6. The fifth resistor R5 includes a first terminal coupled to the second terminal of the first transistor T1, and a second terminal coupled to the ground terminal GND. The sixth capacitor C6 includes a first terminal coupled to the first terminal of the fifth resistor R5, and a second terminal coupled to the ground terminal GND. Here, the fifth resistor R5 is configured to boost the voltage (V_{S1}) of the second terminal of the first transistor T1 so as to change the gate-source voltage of the first transistor to a negative voltage. For example, the first gate bias voltage V_{G1} can be a positive voltage. When the voltage V_{S1} of the first transistor T1 is boosted by the fifth resistor R5 higher than the first gate bias voltage V_{G1} (say, V_{S1}>V_{G1}), the gate-source voltage V_{GS1} of the first transistor T1 is the negative voltage (say, V_{GS1}=V_{G1}−V_{S1}<0). By doing so, the first transistor T1 can be the D-mode FET. The channel can be controlled by the first transistor T1 according to the negative gate-source voltage V_{GS1}. Negative first gate bias voltage V_{G1} is not required. Similarly, it should be understood that any loaded component such as FET or resistor can be applied to the second filtering circuit 11b′ for generating higher positive voltage V_{S1} on the source terminal of the first transistor T1 (D-mode FET).

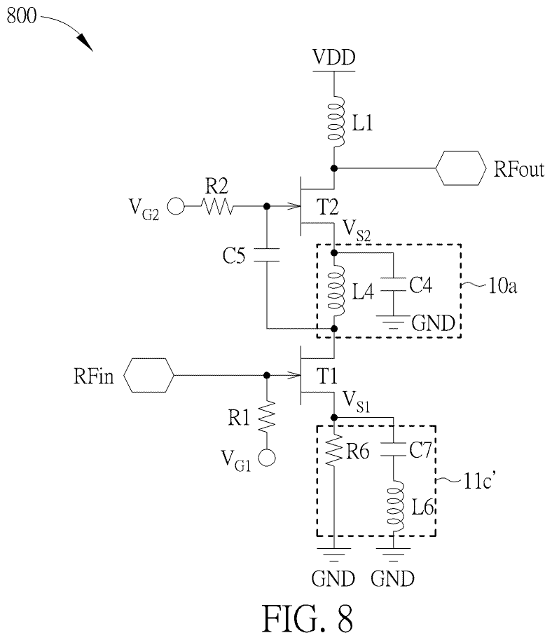

FIG. 8 is a structure of a low noise amplifier circuit 800 according to an eighth embodiment of the present invention. For avoid ambiguity, a low noise amplifier circuit in FIG. 8 is called as the low noise amplifier circuit 800 hereafter. A circuit structure of the low noise amplifier circuit 800 is similar to the circuit structure of the low noise amplifier circuit 500. A difference between the low noise amplifier circuit 500 and the low noise amplifier circuit 800 is the “second filtering circuit 11”, called as the second filtering circuit 11c′ hereafter. In FIG. 8, the second filtering circuit 11c′ includes a sixth resistor R6, a seventh capacitor C7, and a sixth inductor L6. The sixth resistor R6 includes a first terminal coupled to the second terminal of the first transistor T1, and a second terminal coupled to the ground terminal GND. The seventh capacitor C7 includes a first terminal couple to the first terminal of the sixth resistor R6, and a second terminal. The sixth inductor L6 includes a first terminal coupled to the second terminal of the seventh capacitor C7, and a second terminal coupled to the ground terminal GND. Here, the sixth resistor R6 is configured to boost the voltage (V_{S1}) of the second terminal of the first transistor T1 so as to change the gate-source voltage of the first transistor to a negative voltage. For example, the first gate bias voltage V_{G1} can be a positive voltage. When the voltage V_{S1} of the first transistor T1 is boosted by the sixth resistor R6 higher than the first gate bias voltage V_{G1} (say, V_{S1}>V_{G1}), the gate-source voltage V_{GS1} of the first transistor T1 is the negative voltage (say, V_{GS1}=V_{G1}-V_{S1}<0). By doing so, the first transistor T1 can be the D-mode FET. The first transistor T1 can be turned on according to the negative gate-source voltage V_{GS1}. Negative first gate bias voltage V_{G1} is not required. Similarly, it should be understood that any loaded component such as FET or resistor can be applied to the second filtering circuit 11c′ for generating higher positive voltage V_{S1} on the source terminal of the first transistor T1 (D-mode FET).

To sum up, the present invention provides a novel low noise amplifier circuit that effectively addresses the longstanding challenge of balancing low noise performance with high operational linearity. By strategically combining E-mode and D-mode FETs with optimized circuit topologies, the proposed amplifier significantly enhances signal amplification while minimizing noise introduction and improving operational linearity. The incorporation of various filtering circuits and positive bias configurations provides flexibility for tailoring the amplifier to specific application requirements. Therefore, the low noise amplifier circuit of the present invention can be applied to various communication scenarios.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A low noise amplifier circuit comprising:
a first transistor comprising:
a first terminal coupled to a first filtering circuit;
a second terminal coupled to a second filtering circuit; and
a control terminal configured to receive an input signal;
a second transistor comprising:
a first terminal configured to output an output signal;
a second terminal coupled to the first filtering circuit; and
a control terminal; and
a first inductor comprising:
a first terminal coupled to a high voltage terminal; and
a second terminal coupled to the first terminal of the second transistor;
wherein the second filtering circuit is coupled to a ground terminal.

2. The low noise amplifier circuit of claim 1, further comprising:
a first resistor comprising:
a first terminal coupled to the control terminal of the first transistor; and
a second terminal configured to receive a first gate bias voltage;
a second resistor comprising:
a first terminal coupled to the control terminal of the second transistor; and
a second terminal configured to receive a second gate bias voltage; and
a first capacitor comprising:
a first terminal coupled to the first terminal of the second resistor; and
a second terminal coupled to the ground terminal.

3. The low noise amplifier circuit of claim 2, wherein the first gate bias voltage and the second gate bias voltage are positive voltages, and a voltage of the second terminal of the second transistor is greater than the second gate bias voltage.

4. The low noise amplifier circuit of claim 1, wherein the first transistor is an enhancement mode field-effect transistor (E-mode FET), and the second transistor is a depletion mode field-effect transistor (D-mode FET).

5. The low noise amplifier circuit of claim 1, wherein a gate length of the second transistor is greater than a gate length of the first transistor, and the first transistor or the second transistor is formed by a Gallium arsenide (GaAs) semiconductor material or a Gallium nitride (GaN) semiconductor material.

6. The low noise amplifier circuit of claim 1, wherein the first transistor is configured to reduce noise interference from the input signal according to a Friis formula, and the second transistor is configured to enhance operational linearity between the input signal and the output signal.

7. The low noise amplifier circuit of claim 1, wherein the first filtering circuit comprises a first transmission line, the first terminal of the first transistor is coupled to the second terminal of the second transistor through the first transmission line, and the low noise amplifier circuit is a cascode noise amplifier having a common-source configuration device comprising the first transistor and a common-gate configuration device comprising the second transistor.

8. The low noise amplifier circuit of claim 7, wherein the second filtering circuit comprises a second transmission line, the second terminal of the first transistor is coupled to the ground terminal through the second transmission line.

9. The low noise amplifier circuit of claim 7, wherein the second filtering circuit comprises:
a second inductor comprising:
a first terminal coupled to the second terminal of the first transistor; and
a second terminal coupled to the ground terminal;
wherein the first inductor is configured to block an alternating current (AC), and the second inductor is configured to adjust an AC impedance of the first transistor, so as to reduce a leakage signal of the AC to the ground.

10. The low noise amplifier circuit of claim 7, wherein the second filtering circuit comprises:
a third resistor comprising:
a first terminal coupled to the second terminal of the first transistor; and
a second terminal coupled to the ground terminal; and
a second capacitor comprising:
a first terminal coupled to the first terminal of the third resistor; and
a second terminal coupled to the ground terminal;
wherein the third resistor is configured to boost a voltage of the second terminal of the first transistor so as to change a gate-source voltage of the first transistor to a negative voltage.

11. The low noise amplifier circuit of claim 10, wherein the first transistor is a depletion mode field-effect transistor (D-mode FET), the second transistor is the D-mode FET, and when the gate-source voltage of the first transistor is the negative voltage, the first transistor is turned on.

12. The low noise amplifier circuit of claim 7, wherein the second filtering circuit comprises:
a fourth resistor comprising:
a first terminal coupled to the second terminal of the first transistor; and
a second terminal coupled to the ground terminal;
a third capacitor comprising:
a first terminal couple to the first terminal of the fourth resistor; and
a second terminal; and
a third inductor comprising:
a first terminal coupled to the second terminal of the third capacitor; and
a second terminal coupled to the ground terminal;
wherein the fourth resistor is configured to boost a voltage of the second terminal of the first transistor so as to change a gate-source voltage of the first transistor to a negative voltage.

13. The low noise amplifier circuit of claim 12, wherein the first transistor is a depletion mode field-effect transistor (D-mode FET), the second transistor is the D-mode FET, and when the gate-source voltage of the first transistor is negative, the first transistor is turned on.

14. The low noise amplifier circuit of claim 1, wherein the first filtering circuit comprises:
a fourth inductor comprising:
a first terminal coupled to the second terminal of the second transistor; and
a second terminal coupled to the first terminal of the first transistor; and
a fourth capacitor comprising:
a first terminal coupled to the first terminal of the fourth inductor; and
a second terminal coupled to the ground terminal;
wherein the low noise amplifier circuit is a common source low noise amplifier circuit.

15. The low noise amplifier circuit of claim 14, wherein the second filtering circuit comprises a second transmission line, the second terminal of the first transistor is coupled to the ground terminal through the second transmission line.

16. The low noise amplifier circuit of claim 14, wherein the second filtering circuit comprises:
a fifth inductor comprising:
a first terminal coupled to the second terminal of the first transistor; and
a second terminal coupled to the ground terminal;
wherein the first inductor, the fourth inductor, and the fifth inductor are configured to block an alternating current (AC) passing through the low noise amplifier circuit.

17. The low noise amplifier circuit of claim 14, wherein the second filtering circuit comprises:
a fifth resistor comprising:
a first terminal coupled to the second terminal of the first transistor; and
a second terminal coupled to the ground terminal; and
a sixth capacitor comprising:
a first terminal coupled to the first terminal of the fifth resistor; and
a second terminal coupled to the ground terminal;
wherein the fifth resistor is configured to boost a voltage of the second terminal of the first transistor so as to change a gate-source voltage of the first transistor to a negative voltage.

18. The low noise amplifier circuit of claim 17, wherein the first transistor is a depletion mode field-effect transistor (D-mode FET), the second transistor is the D-mode FET, and when the gate-source voltage of the first transistor is the negative voltage, the first transistor is turned on.

19. The low noise amplifier circuit of claim 14, wherein the second filtering circuit comprises:
a sixth resistor comprising:
a first terminal coupled to the second terminal of the first transistor; and
a second terminal coupled to the ground terminal;
a seventh capacitor comprising:
a first terminal couple to the first terminal of the sixth resistor; and
a second terminal; and
a sixth inductor comprising:
a first terminal coupled to the second terminal of the seventh capacitor; and
a second terminal coupled to the ground terminal;
wherein the sixth resistor is configured to boost a voltage of the second terminal of the first transistor so as to change a gate-source voltage of the first transistor to a negative voltage.

20. The low noise amplifier circuit of claim 14, wherein the first transistor is a depletion mode field-effect transistor (D-mode FET), the second transistor is the D-mode FET, and when the gate-source voltage of the first transistor is the negative voltage, the first transistor is turned on.
